(19) United States
(12) Patent Application Publication
(10) Pub. No.: US 2009/0051035 A1
(43) Pub. Date: Feb. 26, 2009

(54) SEMICONDUCTOR INTEGRATED CIRCUIT

(76) Inventors: Hiroshige HIRANO, Nara (JP); Koji TAKEMURA, Osaka (JP); Koji KOIKE, Osaka (JP)

Correspondence Address: MCDERMOTT WILL & EMERY LLP, 600 13TH STREET, NW, WASHINGTON, DC, 20005-3096, US

(21) Appl. No.: 12/194,076

(22) Filed: Aug. 19, 2008

(30) Foreign Application Priority Data
Aug. 24, 2007 (JP) 2007-218422

(51) Int. Cl. H01L 23/532

(52) U.S. Cl. 257/758; 257/E23.157

(57) ABSTRACT

The semiconductor integrated circuit includes: a first wiring layer including a plurality of first interconnects formed to run in a first direction; a second wiring layer formed above the first wiring layer, the second wiring layer including a plurality of second interconnects formed to run in a second direction vertical to the first direction; and a third wiring layer formed above the second wiring layer, the third wiring layer including a plurality of third interconnects formed to run in the same direction as the second direction.

### BACKGROUND OF THE INVENTION

The present invention relates to a wiring structure of a semiconductor integrated circuit, and more particularly to a power wiring structure of a semiconductor integrated circuit.

When the power wiring of a semiconductor integrated circuit is formed of a plurality of wiring layers, it generally has a meshed or similar wiring structure.

FIGS. 19A and 19B show a conventional semiconductor integrated circuit having a meshed wiring structure, in which FIG. 19A is a plan view and FIG. 19B is a cross-sectional view taken along line XIXb-XIXb in FIG. 19A.

As shown in FIGS. 19A and 19B, the meshed wiring structure of the conventional semiconductor integrated circuit is formed over the n-th and (n+1)th layers, for example. That is, over the entire chip not shown, a wiring layer 1 is formed in the n-th layer, which includes a plurality of interconnects 1D for power supply voltage and a plurality of interconnects 1S for ground voltage arranged to alternate one by one. Also, a wiring layer 2 is formed in the (n+1)th layer, which includes a plurality of interconnects 2D for power supply voltage and a plurality of interconnects 2S for ground voltage arranged to alternate one by one in a direction vertical to the direction of running of the interconnects 1D and 1S. The interconnects 1D and the interconnects 2D for power supply voltage are electrically connected to each other via contacts 3 at the positions of intersection of these interconnects as viewed from top. Likewise, the interconnects 1S and the interconnects 2S for ground voltage are electrically connected to each other via contacts 3 at the positions of intersection of these interconnects as viewed from top (see Japanese Laid-Open Patent Publication No. 2005-332903, for example).

In the semiconductor integrated circuit having the meshed power wiring structure described above, a current is supplied from outside toward inside through the power wiring network that spreads in a mesh form. The current supplied through the power wiring network is received and consumed by cells inside at respective internal points of the semiconductor integrated circuit. In the power wiring network, therefore, the voltage drop becomes greater as the position in a chip is closer to the center thereof from the periphery thereof. In other words, the voltage on the power wiring network is generally high in the peripheral portion of a semiconductor integrated circuit and becomes lower as the position is closer to the center.

In the semiconductor integrated circuit having the meshed power wiring structure described above, if the wiring layer in the n-th layer and the wiring layer in the (n+1)th layer are different in film thickness or material from each other, resulting in a difference in wiring resistance, the voltage drop will be greater in the wiring layer higher in wiring resistance, and the influence of this wiring layer will be dominant.

FIG. 20 schematically shows a voltage drop observed when a power supply voltage is applied via pads 6 and 7 in the semiconductor integrated circuit having the meshed power wiring structure described above. It is herein assumed that the wiring resistance of the wiring layer 2 including a plurality of interconnects running vertically as viewed from FIG. 20 is higher than the wiring resistance of the wiring layer 1 including a plurality of interconnects running horizontally as viewed from FIG. 20. Regions 8, 9 and 10 respectively represent regions small, middle and large in voltage drop.

From FIG. 20 it is found that the voltage drop is larger in the center portion of the chip than in the peripheral portion thereof and that the directivity of the voltage drop obeys the direction of running of the interconnects of the wiring layer 2 greater in wiring resistance than the wiring layer 1.

To suppress the voltage drop, measures like increasing the number of power supply pads and thickening the power interconnects may be taken. These measures however have their limits due to restrictions of the chip size and the like.

### SUMMARY OF THE INVENTION

An object of the present invention is providing a semiconductor integrated circuit having a wiring structure capable of suppressing the voltage drop by reducing the wiring resistance.

To attain the above object, the first semiconductor integrated circuit of the present invention includes: a first wiring layer including a plurality of first interconnects formed to run in a first direction; a second wiring layer formed above the first wiring layer, the second wiring layer including a plurality of second interconnects formed to run in a second direction vertical to the first direction; and a third wiring layer formed above the second wiring layer, the third wiring layer including a plurality of third interconnects formed to run in the same direction as the second direction.

In the first semiconductor integrated circuit described above, the second wiring layer and the third wiring layer may be electrically connected to each other.

In the first semiconductor integrated circuit described above, the first wiring layer and the second wiring layer may be made of copper, and the third wiring layer may be made of aluminum.

In the first semiconductor integrated circuit described above, the third wiring layer may be made of the same material as pads.

In the first semiconductor integrated circuit described above, each of the plurality of third interconnects may be wider than each of the plurality of second interconnects.

In the first semiconductor integrated circuit described above, each of the plurality of third interconnects may be formed to cover two adjacent ones of the plurality of second interconnects.

In the first semiconductor integrated circuit described above, each of the plurality of third interconnects may not be formed above an interconnect located next to the two adjacent ones among the plurality of second interconnects.

In the case described above, the first wiring layer may include interconnects for power supply voltage as the first interconnects and interconnects for ground voltage as the first interconnects arranged to alternate one by one, the second wiring layer may include interconnects for power supply voltage as the second interconnects and interconnects for ground voltage as the second interconnects arranged to alternate every three interconnects, and the third wiring layer may include interconnects for power supply voltage as the third interconnects and interconnects for ground voltage as the third interconnects arranged to alternate one by one.

In the first semiconductor integrated circuit described above, each of the plurality of third interconnects may have a portion formed to cover two adjacent ones of the plurality of second interconnects and a portion formed to cover only one of the two adjacent ones, along the running of the third interconnect.

In the case described above, the first wiring layer may include interconnects for power supply voltage as the first interconnects and interconnects for ground voltage as the first interconnects arranged to alternate one by one, the second wiring layer may include interconnects for power supply voltage as the second interconnects and interconnects for ground voltage as the second interconnects arranged to alternate every two interconnects, and the third wiring layer may include interconnects for power supply voltage as the third interconnects and interconnects for ground voltage as the third interconnects arranged to alternate one by one.

The second semiconductor integrated circuit of the present invention includes: at least one wiring block including a two by two matrix of meshed power arrays, each of the meshed power arrays having a first wiring layer including a plurality of first interconnects and a second wiring layer formed above the first wiring layer, the second wiring layer including a plurality of second interconnects formed to run in a direction vertical to the direction of running of the plurality of first interconnects, the meshed power arrays being lined in the direction of running of the plurality of first interconnects and in the direction of running of the plurality of second interconnects, the direction of running of the plurality of first interconnects in one of the meshed power arrays constituting the wiring block is displaced by 90° with respect to the direction of running of the plurality of first interconnects in a meshed power array adjacent to the one meshed power array, and the direction of running of the plurality of second interconnects in one of the meshed power arrays constituting the wiring block is displaced by 90° with respect to the direction of running of the plurality of second interconnects in a meshed power array adjacent to the one meshed power array.

The second semiconductor integrated circuit described above may further include a third wiring layer including a plurality of third interconnects formed above the second wiring layer, wherein the plurality of third interconnects run in one direction above all the meshed power arrays, and the direction is the same as the direction of running of the plurality of first interconnects or the direction of running of the plurality of second interconnects in each of the meshed power arrays.

The second semiconductor integrated circuit described above may further include a third wiring layer including a plurality of third interconnects formed above the second wiring layer in each of the meshed power arrays, wherein the plurality of third interconnects run in the same direction as the direction of running of the plurality of second interconnects in each of the meshed power arrays.

In the second semiconductor integrated circuit described above, the second wiring layer and the third wiring layer may be electrically connected to each other.

According to the present invention, by reducing the wiring resistance, a wiring structure capable of suppressing the voltage drop is implemented.

### BRIEF DESCRIPTION OF THE DRAWINGS

FIG. 1 is a plan view showing a power wiring structure of a semiconductor integrated circuit of Embodiment 1 of the present invention.

FIGS. 2A and 2B are cross-sectional views of the power wiring structure of the semiconductor integrated circuit of Embodiment 1, taken along line IIa-IIa and line IIb-IIb in FIG. 1, respectively.

FIG. 3 is a view schematically showing the voltage drop in the semiconductor integrated circuit having the power wiring structure of Embodiment 1.

FIG. 4 is a plan view showing a power wiring structure of a semiconductor integrated circuit of Embodiment 2 of the present invention.

FIGS. 5A and 5B are cross-sectional views of the power wiring structure of the semiconductor integrated circuit of Embodiment 2, taken along line Va-Va and line Vb-Vb in FIG. 4, respectively.

FIG. 6 is a plan view showing a power wiring structure of a semiconductor integrated circuit of Embodiment 3 of the present invention.

FIGS. 7A and 7B are cross-sectional views of the power wiring structure of the semiconductor integrated circuit of Embodiment 3, taken along line VIIa-VIIa and line VIIb-VIIb in FIG. 6, respectively.

FIG. 8 is a plan view showing a power wiring structure of a semiconductor integrated circuit of Embodiment 4 of the present invention.

FIGS. 9A and 9B are cross-sectional views of the power wiring structure of the semiconductor integrated circuit of Embodiment 4, taken along line IXa-IXa and line IXb-IXb in FIG. 8, respectively.

FIG. 10 is a plan view showing a power wiring structure of a semiconductor integrated circuit of Embodiment 5 of the present invention.

FIGS. 11A and 11B are cross-sectional views of the power wiring structure of the semiconductor integrated circuit of Embodiment 5, taken along line XIa-XIa and line XIb-XIb in FIG. 10, respectively.

FIG. 12 is a view schematically showing the voltage drop in the semiconductor integrated circuit having the power wiring structure of Embodiment 5.

FIG. 13 is a plan view of a power wiring structure of a semiconductor integrated circuit of Embodiment 5.

FIG. 14 is a view schematically showing the voltage drop in the semiconductor integrated circuit having the power wiring structure of FIG. 13.

FIG. 15 is a plan view showing a power wiring structure of a semiconductor integrated circuit of Embodiment 6 of the present invention.

FIGS. 16A and 16B are cross-sectional views of the power wiring structure of the semiconductor integrated circuit of Embodiment 6, taken along line XVIa-XVIa and line XVIb-XVIb in FIG. 15, respectively.

FIG. 17 is a plan view showing a power wiring structure of a semiconductor integrated circuit of Embodiment 7 of the present invention.

FIGS. 18A and 18B are cross-sectional views of the power wiring structure of the semiconductor integrated circuit of Embodiment 6, taken along line XVIIIa-XVIIIa and line XVIIIb-XVIIIb in FIG. 17, respectively.

FIG. 19A is a plan view showing a power wiring structure of a conventional semiconductor integrated circuit, and FIG. 19B is a cross-sectional view taken along line XIXb-XIXb in FIG. 19A.

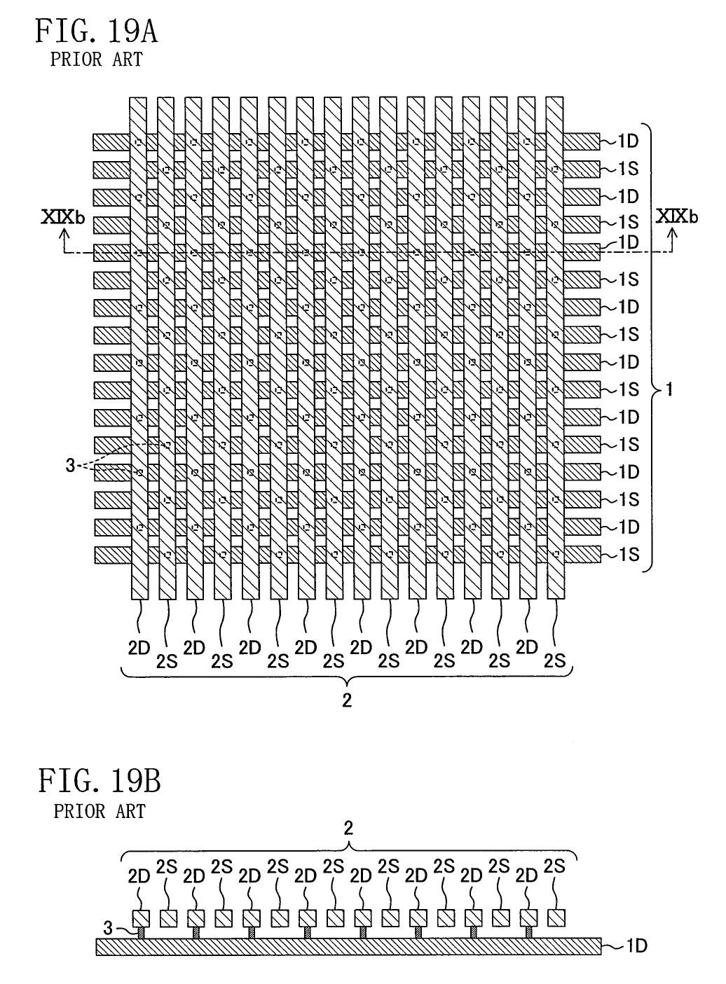

FIG. 20 is a view schematically showing the voltage drop in the conventional semiconductor integrated circuit having the power wiring structure.

### DESCRIPTION OF THE PREFERRED EMBODIMENTS

Hereinafter, preferred embodiments of the present invention will be described with reference to the accompanying drawings.

### Embodiment 1

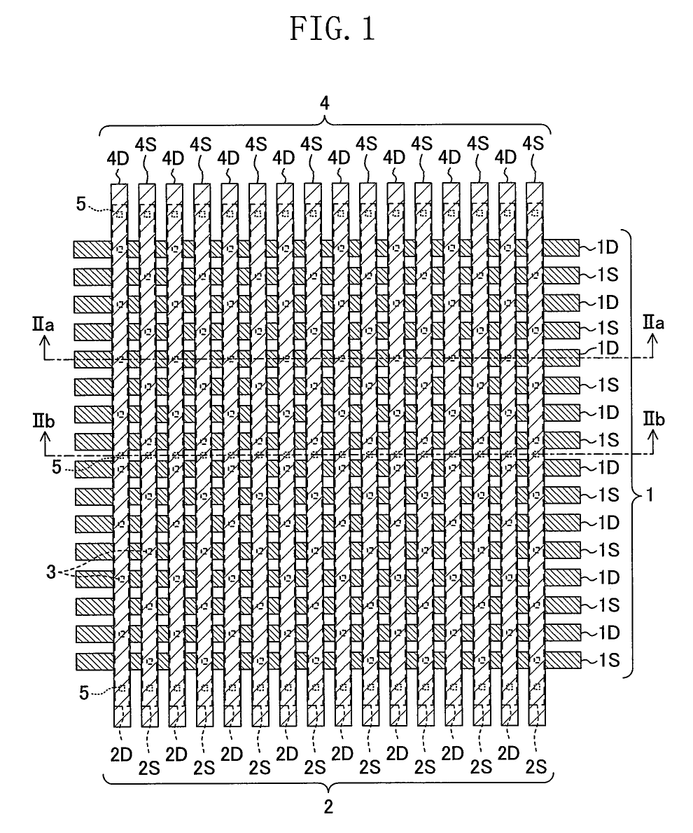

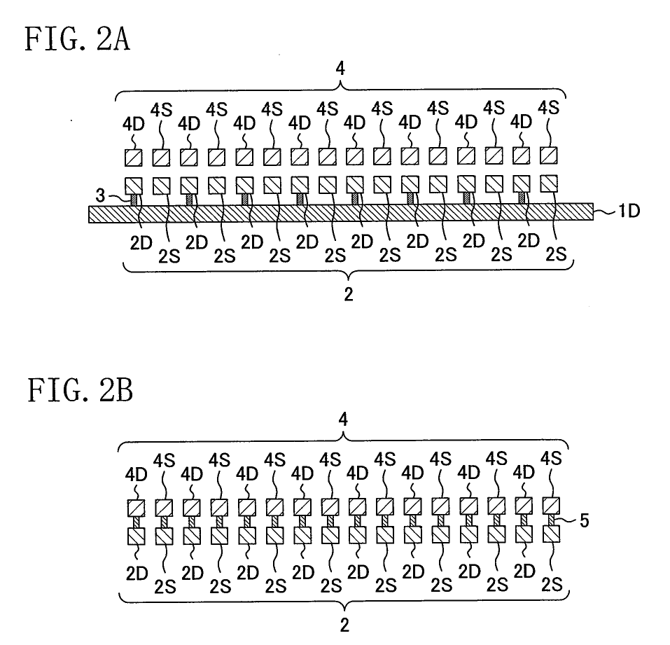

FIG. 1 is a plan view showing a power wiring structure of a semiconductor integrated circuit of Embodiment 1 of the present invention. FIGS. 2A and 2B are cross-sectional views of the power wiring structure of the semiconductor integrated circuit of Embodiment 1, taken along line IIa-IIa and line IIb-IIb in FIG. 1, respectively.

As shown in FIGS. 1, 2A and 2B, in the power wiring structure of the semiconductor integrated circuit of Embodiment 1, a wiring layer 1 including a plurality of interconnects 1D for power supply voltage and a plurality of interconnects 1S for ground voltage arranged to alternate one by one is formed on a semiconductor substrate not shown. The interconnects 1D and 1S are made of copper, for example.

On the wiring layer 1, formed via a first interlayer insulating film (not shown) is a wiring layer 2 including a plurality of interconnects 2D for power supply voltage and a plurality of interconnects 2S for ground voltage arranged to alternate one by one in a direction vertical to the direction of running of the interconnects 1D and 1S. The wiring layer 1 and the wiring layer 2 have a resistance difference therebetween due to their difference in film thickness or material. The wiring resistance of the wiring layer 2 is equal to or less than that of the wiring layer 1, having a resistance value 0.5 to 1.0 times as large as that of the wiring layer 1. The interconnects 2D and 2S are made of copper, for example.

The interconnects 1D and the interconnects 2D for power supply voltage are electrically connected to each other via contacts 3 formed through the first interlayer insulating film (not shown) at the positions of intersection of these interconnects as viewed from top (see FIGS. 1 and 2A). Likewise, the interconnects 1S and the interconnects 2S for ground voltage are electrically connected to each other via contacts 3 formed through the first interlayer insulating film (not shown) at the positions of intersection of these interconnects as viewed from top (see FIG. 1). The contacts 3 are made of copper, for example.

On the wiring layer 2, formed via a second interlayer insulating film (not shown) is a wiring layer 4 including a plurality of interconnects 4D for power supply voltage and a plurality of interconnects 4S for ground voltage arranged to alternate one by one. The interconnects 4D and 4S are provided in one-to-one correspondence with the interconnects 2D and 2S to run in the same direction as the interconnects 2D and 2S. The interconnects 4D and 4S are made of aluminum, for example, or alternatively may be formed of the same material as a wiring layer constituting pads not shown.

The interconnects 2D and the interconnects 4D for power supply voltage are electrically connected to each other via contacts 5 formed through the second interlayer insulating film (not shown) (see FIGS. 1 and 2B). Likewise, the interconnects 2S and the interconnects 4S for ground voltage are electrically connected to each other via contacts 5 formed through the second interlayer insulating film (not shown) (see FIG. 1). The contacts 5 are made of copper, for example. Although the wiring layer 2 and the wiring layer 4 are electrically connected to each other to have the same potential in the illustrated example, this embodiment is not necessarily limited to the configuration giving the same potential.

In the semiconductor integrated circuit having the power wiring structure of this embodiment described above, the interconnects 4D and 4S constituting the wiring layer 4 are respectively formed to cover the corresponding interconnects 2D and 2S constituting the wiring layer 2. The direction of running of the interconnects 4D and 4S constituting the wiring layer 4 is the same as the direction of running of the interconnects 2D and 2S constituting the wiring layer 2. Also, the wiring layer 4 and the wiring layer 2 are electrically connected to each other via the contacts 5 formed through the second interlayer insulating film (not shown) to have the same potential. The wiring resistance can therefore be reduced, and as a result, the voltage drop can be reduced.

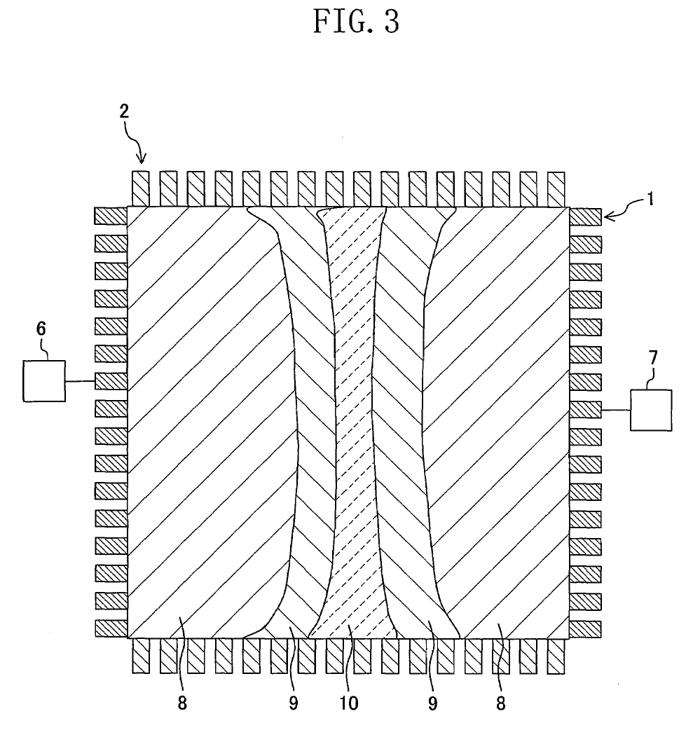

FIG. 3 schematically shows a voltage drop in the semiconductor integrated circuit having the power wiring structure of this embodiment during operation observed when a power supply voltage is applied via pads 6 and 7. Regions 8, 9 and 10 respectively represent regions small, middle and large in voltage drop.

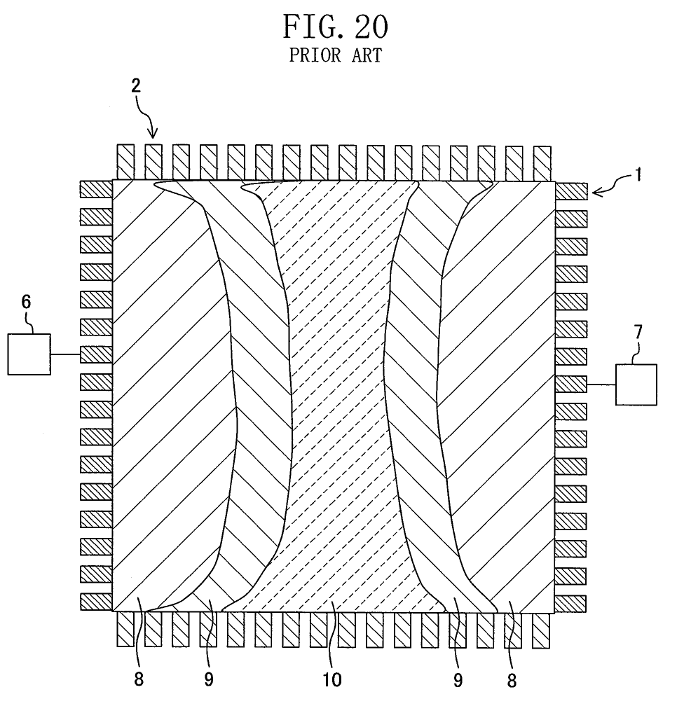

As shown in FIG. 3, in this embodiment, compared with the case of the conventional semiconductor integrated circuit having the power wiring structure described above (see FIG. 20), the region 8 small in voltage drop is wider while the region 10 large in voltage drop and the region 9 middle in voltage drop are narrower. This indicates that with the wiring layer 4 serving to intensify the power supply signal and thus reduce the resistance of the wiring layer 2, the voltage drop in this embodiment has been widely reduced.

Also, with the wiring layer 4 being at the same potential as the wiring layer 2, it is unnecessary to consider the insulation property of the second interlayer insulating film existing between the wiring layer 4 and the wiring layer 2.

In the above description, the interconnects (1D, 2D, 4D) for power supply voltage and the interconnects (1S, 2S, 4S) for ground voltage are arranged to alternate one by one. This embodiment is not limited to this configuration, but substantially the same effect as that described above can also be obtained by arranging the interconnects (1D, 2D, 4D) for power supply voltage and the interconnects (1S, 2S, 4S) for ground voltage to alternate every two interconnects.

### Embodiment 2

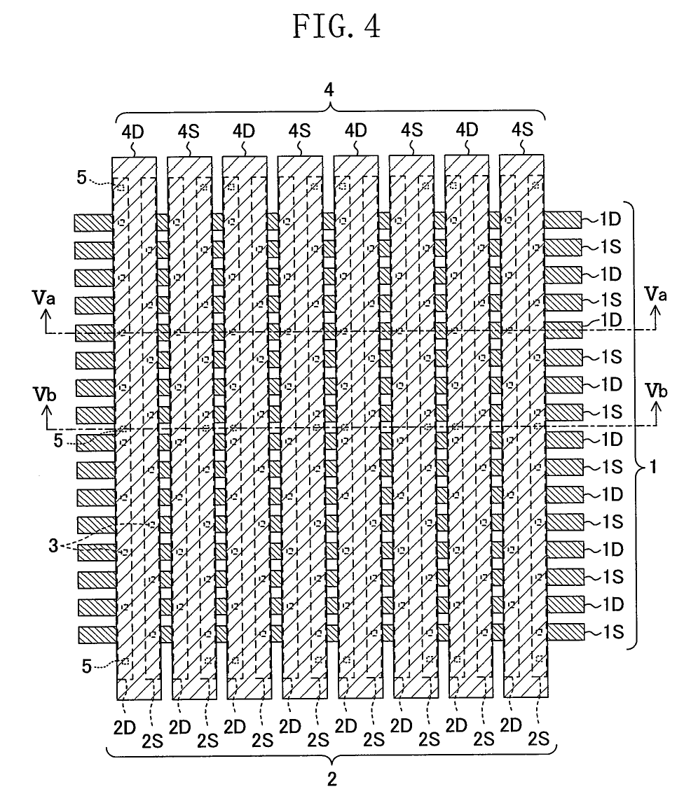

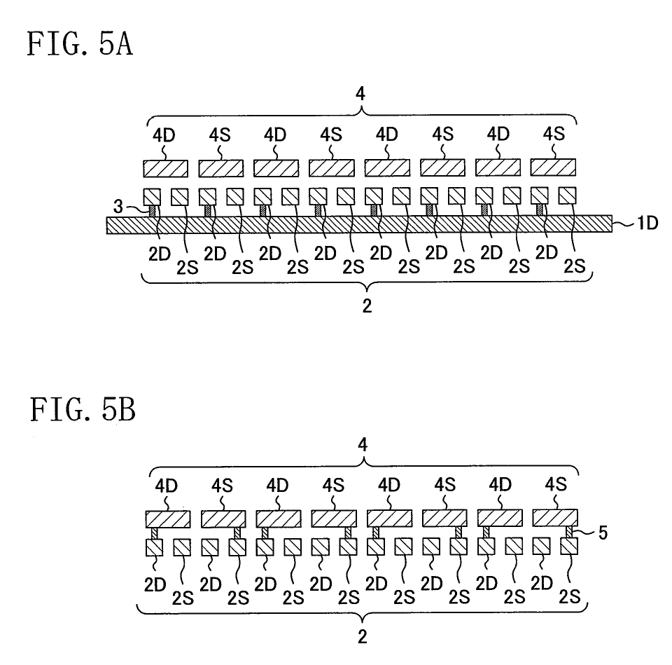

FIG. 4 is a plan view showing a power wiring structure of a semiconductor integrated circuit of Embodiment 2 of the present invention. FIGS. 5A and 5B are cross-sectional views of the power wiring structure of the semiconductor integrated circuit of Embodiment 2, taken along line Va-Va and line Vb-Vb in FIG. 4, respectively.

As shown in FIGS. 4, 5A and 5B, in the wiring structure of the semiconductor integrated circuit of Embodiment 2, a wiring layer 1 including a plurality of interconnects 1D for power supply voltage and a plurality of interconnects 1S for ground voltage arranged to alternate one by one is formed on a semiconductor substrate not shown. The interconnects 1D and 1S are made of copper, for example.

On the wiring layer 1, formed via a first interlayer insulating film (not shown) is a wiring layer 2 including a plurality of interconnects 2D for power supply voltage and a plurality of interconnects 2S for ground voltage arranged to alternate one by one in a direction vertical to the direction of running of the interconnects 1D and 1S. The wiring layer 1 and the wiring layer 2 have a resistance difference therebetween due to their difference in film thickness or material. The wiring resistance of the wiring layer 2 is equal to or less than that of the wiring layer 1, having a resistance value 0.5 to 1.0 times as large as that of the wiring layer 1. The interconnects 2D and 2S are made of copper, for example.

The interconnects 1D and the interconnects 2D for power supply voltage are electrically connected to each other via contacts 3 formed through the first interlayer insulating film (not shown) at the positions of intersection of these interconnects as viewed from top (see FIGS. 4 and 5A). Likewise, the interconnects 1S and the interconnects 2S for ground voltage are electrically connected to each other via contacts 3 formed through the first interlayer insulating film (not shown) at the positions of intersection of these interconnects as viewed from top (see FIG. 4). The contacts 3 are made of copper, for example.

On the wiring layer 2, formed via a second interlayer insulating film (not shown) is a wiring layer 4 including a plurality of interconnects 4D for power supply voltage and a plurality of interconnects 4S for ground voltage arranged to alternate one by one. The interconnects 4D and 4S are respectively provided on the basis of one for every two of the interconnects 2D and 2S in the same direction as the interconnects 2D and 2S. The interconnects 4D and 4S are made of aluminum, for example, or alternatively may be formed of the same material as a wiring layer constituting pads not shown. Hence, the power wiring structure of this embodiment is different from that of Embodiment 1 described above in that the wiring layer 4 includes the interconnects 4D and 4S respectively provided on the basis of one for every two of the interconnects 2D and 2S, and that the wiring width of interconnects 4D and 4S is equal to the distance between the side faces of any adjacent interconnects 2D and 2S located apart from each other (i.e., the sum of the two widths of the interconnects 2D and 2S and the gap between the interconnects 2D and 2S).

The interconnects 2D and the interconnects 4D for power supply voltage are electrically connected to each other via contacts 5 formed through the second interlayer insulating film (not shown) (see FIGS. 4 and 5B). Likewise, the interconnects 2S and the interconnects 4S for ground voltage are electrically connected to each other via contacts 5 formed through the second interlayer insulating film (not shown) (see FIG. 4). The contacts 5 are made of copper, for example. Although the wiring layer 2 and the wiring layer 4 are electrically connected to each other to have the same potential in the illustrated example, this embodiment is not necessarily limited to the configuration giving the same potential.

The semiconductor integrated circuit having the power wiring structure of this embodiment can obtain substantially the same effect as that in Embodiment 1 described above. In this embodiment, also, since the interconnects 4D and 4S of the wiring layer 4 are thickened to cover every two of the interconnects 2D and 2S constituting the wiring layer 2, the resistance can further be reduced and thus the voltage drop can be further suppressed.

The wiring width of the interconnects 4D and 4S constituting the wiring layer 4 is not limited to that described above, but may be a value within the range that is larger than the wiring width of each of the interconnects 2D and 2S constituting the wiring layer 2 but is not large enough to reach above an interconnect located next to the adjacent two interconnects. With this configuration, also, substantially the same effect as that described above can be obtained.

### Embodiment 3

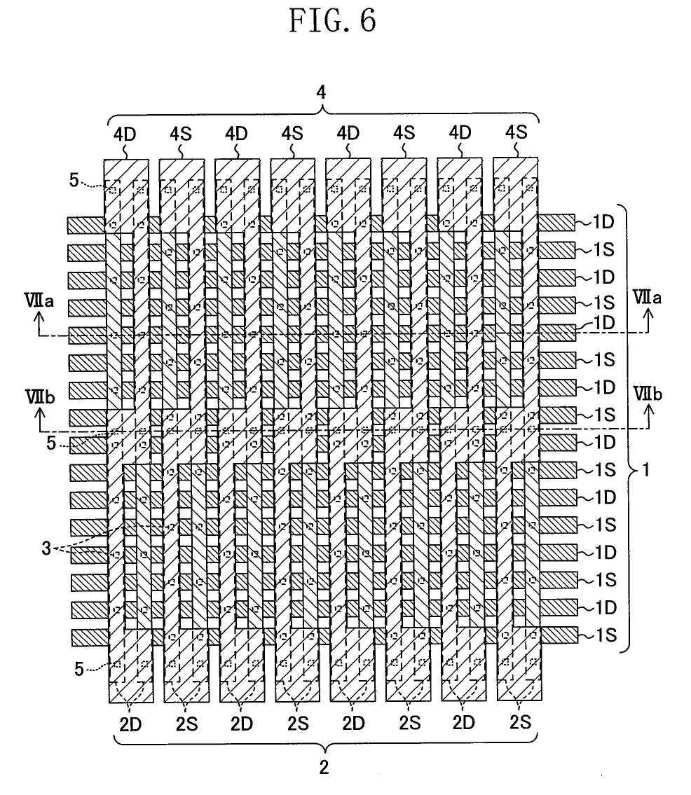

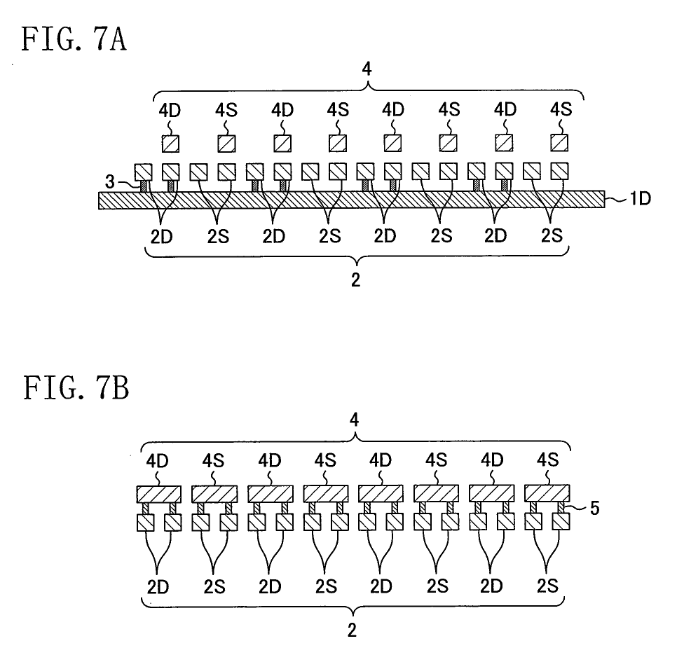

FIG. 6 is a plan view showing a power wiring structure of a semiconductor integrated circuit of Embodiment 3 of the present invention. FIGS. 7A and 7B are cross-sectional views of the power wiring structure of the semiconductor integrated circuit of Embodiment 3, taken along line VIIa-VIIa and line VIIb-VIIb in FIG. 6, respectively.

As shown in FIGS. 6, 7A and 7B, in the wiring structure of the semiconductor integrated circuit of Embodiment 3, a wiring layer 1 including a plurality of interconnects 1D for power supply voltage and a plurality of interconnects 1S for ground voltage arranged to alternate one by one is formed on a semiconductor substrate not shown. The plurality of interconnects 1D and 1S are made of copper, for example.

On the wiring layer 1, formed via a first interlayer insulating film (not shown) is a wiring layer 2 including a plurality of interconnects 2D for power supply voltage and a plurality of interconnects 2S for ground voltage arranged to alternate every two interconnects in a direction vertical to the direction of running of the interconnects 1D and 1S. The wiring layer 1 and the wiring layer 2 have a resistance difference therebetween due to their difference in film thickness or material. The wiring resistance of the wiring layer 2 is equal to or less than that of the wiring layer 1, having a resistance value 0.5 to 1.0 times as large as that of the wiring layer 1. The interconnects 2D and 2S are made of copper, for example.

The interconnects 1D and the interconnects 2D for power supply voltage are electrically connected to each other via contacts 3 formed through the first interlayer insulating film (not shown) at the positions of intersection of these interconnects as viewed from top (see FIGS. 6 and 7A). Likewise, the interconnects 1S and the interconnects 2S for ground voltage are electrically connected to each other via contacts 3 formed through the first interlayer insulating film (not shown) at the positions of intersection of these interconnects as viewed from top (see FIG. 6). The contacts 3 are made of copper, for example.

On the wiring layer 2, formed via a second interlayer insulating film (not shown) is a wiring layer 4 including a plurality of interconnects 4D for power supply voltage and a plurality of interconnects 4S for ground voltage arranged to alternate one by one. The interconnects 4D and 4S are respectively provided on the basis of one for every two of the interconnects 2D and 2S in the same direction as the interconnects 2D and 2S. More specifically, each of the interconnects 4D and 4S constituting the wiring layer 4 has a portion formed to cover two of the interconnects 2D or 2S and a portion formed to cover only one of the two interconnects. The interconnects 4D and 4S are made of aluminum, for example, or alternatively may be formed of the same material as a wiring layer constituting pads not shown. Hence, the power wiring structure of this embodiment, in which the wiring layer 4 includes the interconnects 4D and 4S respectively provided on the basis of one for every two of the interconnects 2D and 2S and each of the interconnects 4D and 4S has a portion formed to cover two of the interconnects 2D or 2S and a portion formed to cover only one of the two interconnects, is different from that of Embodiment 2 described above in which the wiring layer 4 is formed to cover every two of the interconnects 2D and 2S entirely.

The interconnects 2D and the interconnects 4D for power supply voltage are electrically connected to each other via contacts 5 formed through the second interlayer insulating film (not shown) (see FIGS. 6 and 7B). Likewise, the interconnects 2S and the interconnects 4S for ground voltage are electrically connected to each other via contacts 5 formed through the second interlayer insulating film (not shown) (see FIG. 6). The contacts 5 are made of copper, for example. Although the wiring layer 2 and the wiring layer 4 are electrically connected to each other to have the same potential in the illustrated example, this embodiment is not necessarily limited to the configuration giving the same potential.

The semiconductor integrated circuit having the power wiring structure of this embodiment can obtain substantially the same effect as that in Embodiment 1 described above because the interconnects of the wiring layer 4 run in the same direction as the interconnects of the wiring layer 2, and also obtain substantially the same effect as that in Embodiment 2 described above because part of the interconnects 4D and 4S constituting the wiring layer 4 are thickened. In addition, the configuration of this embodiment is effective in the case that the area ratio of the wiring layer 4 is restricted, because each of the interconnects 4D and 4S of the wiring layer 4 has a portion formed to cover two of the interconnects 2D or 2S and a portion formed to cover only one of the two interconnects. Moreover, since the interconnects 4D and 4S constituting the wiring layer 4 are not formed to cover every two of the interconnects 2D and 2S entirely, unlike the power wiring structure of Embodiment 2, the stress of the wiring layer 4 can be reduced to suppress damage to the insulating film or another wiring layer.

The wiring width of the interconnects 4D and 4S constituting the wiring layer 4 is not limited to that described above, but, like Embodiment 2, the wiring layer 4 can be configured to have a wiring width within the range that is larger than the wiring width of each of the interconnects 2D and 2S of the wiring layer 2 but is not large enough to reach above an interconnect located next to the adjacent two interconnects.

### Embodiment 4

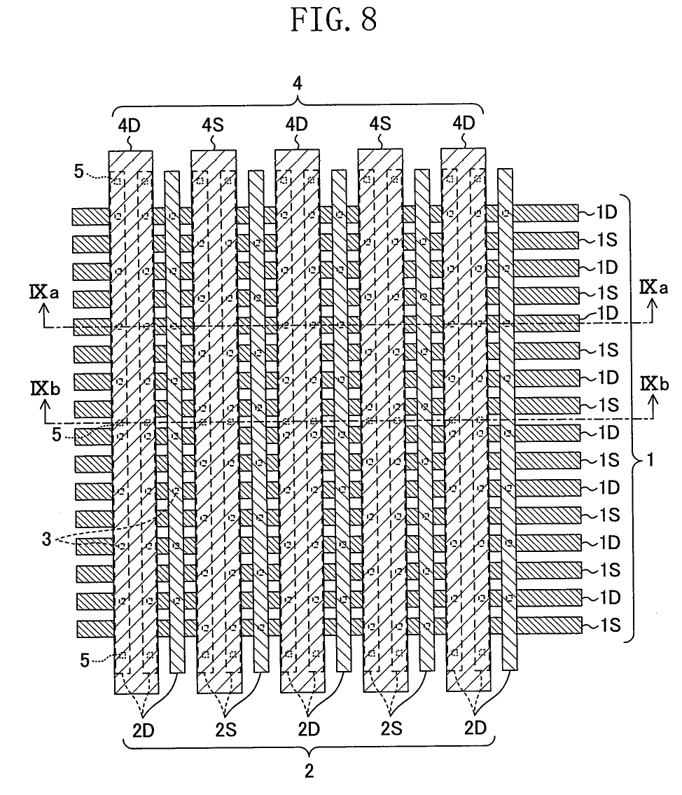

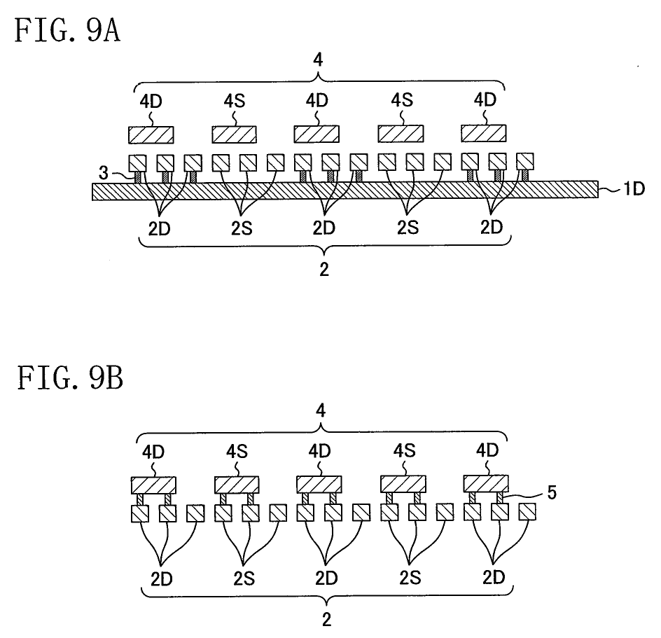

FIG. 8 is a plan view showing a power wiring structure of a semiconductor integrated circuit of Embodiment 4 of the present invention. FIGS. 9A and 9B are cross-sectional views of the power wiring structure of the semiconductor integrated circuit of Embodiment 4, taken along line IXa-IXa and line IXb-IXb in FIG. 8, respectively.

As shown in FIGS. 8, 9A and 9B, in the wiring structure of the semiconductor integrated circuit of Embodiment 4, a wiring layer 1 including a plurality of interconnects 1D for power supply voltage and a plurality of interconnects 1S for ground voltage arranged to alternate one by one is formed on a semiconductor substrate not shown. The interconnects 1D and 1S are made of copper, for example.

On the wiring layer 1, formed via a first interlayer insulating film (not shown) is a wiring layer 2 including a plurality of interconnects 2D for power supply voltage and a plurality of interconnects 2S for ground voltage arranged to alternate every three interconnects in a direction vertical to the direction of running of the interconnects 1D and 1S. The wiring layer 1 and the wiring layer 2 have a resistance difference therebetween due to their difference in film thickness or material. The wiring resistance of the wiring layer 2 is equal to or less than that of the wiring layer 1, having a resistance value 0.5 to 1.0 times as large as that of the wiring layer 1. The interconnects 2D and 2S are made of copper, for example.

The interconnects 1D and the interconnects 2D for power supply voltage are electrically connected to each other via contacts 3 formed through the first interlayer insulating film (not shown) at the positions of intersection of these interconnects as viewed from top (see FIGS. 8 and 9A). Likewise, the interconnects 1S and the interconnects 2S for ground voltage are electrically connected to each other via contacts 3 formed through the first interlayer insulating film (not shown) at the positions of intersection of these interconnects as viewed from top (see FIG. 8). The contacts 3 are made of copper, for example.

On the wiring layer 2, formed via a second interlayer insulating film (not shown) is a wiring layer 4 including a plurality of interconnects 4D for power supply voltage and a plurality of interconnects 4S for ground voltage arranged to alternate one by one. The interconnects 4D and 4S are respectively provided on the basis of one for every two of the interconnects 2D and 2S in the same direction as the interconnects 2D and 2S. Each of the interconnects 4D is formed to cover two adjacent ones out of the three adjacent interconnects 2D and not to cover the remaining one. Likewise, each of the interconnects 4S is formed to cover two adjacent ones out of the three adjacent interconnects 2S and not to cover the remaining one. In other words, one interconnect 2D or 2S exists between any adjacent interconnects 4D and 4S. The interconnects 4D and 4S are made of aluminum, for example, or alternatively may be formed of the same material as a wiring layer constituting pads not shown. Hence, the power wiring structure of this embodiment is different from that of Embodiment 2 described above in that the wiring layer 4 includes the interconnects 4D each formed to cover two adjacent ones out of the three adjacent interconnects 2D and not to cover the remaining one and the plurality of interconnects 4S each formed to cover two adjacent ones out of the three adjacent interconnects 2S and not to cover the remaining one.

The interconnects 2D and the interconnects 4D for power supply voltage are electrically connected to each other via contacts 5 formed through the second interlayer insulating film (not shown) (see FIGS. 8 and 9B). Likewise, the interconnects 2S and the interconnects 4S for ground voltage are electrically connected to each other via contacts 5 formed through the second interlayer insulating film (not shown) (see FIG. 8). The contacts 5 are made of copper, for example. Although the wiring layer 2 and the wiring layer 4 are electrically connected to each other to have the same potential in the illustrated example, this embodiment is not necessarily limited to the configuration giving the same potential.

The semiconductor integrated circuit having the power wiring structure of this embodiment can obtain substantially the same effect as that in Embodiment 1 described above because the interconnects of the wiring layer 4 run in the same direction as the interconnects of the wiring layer 2, and also substantially the same effect as that in Embodiment 2 described above because the interconnects 4D and 4S constituting the wiring layer 4 are thickened. In addition, like Embodiment 3 described above, since each of the interconnects 4D and 4S does not cover one of three adjacent interconnects 2D or 2S, this embodiment is effective in the case that the area ratio is restricted, and moreover, can obtain the effect of reducing damage to the insulating film or another wiring layer.

The width of each of the interconnects 4D and 4S of the wiring layer 4 is not limited to that described above, but the wiring layer 4 in this embodiment can be configured to have a wiring width within the range that is larger than the width covering two adjacent ones out of three adjacent interconnects 2D or 2S but is not large enough to reach above an interconnect located next to the adjacent two interconnects.

In the above description, the interconnects 4D and 4S constituting the wiring layer 4 are respectively arranged at equal pitches. Alternatively, the gap may be widened between the interconnects 4D for power supply voltage and the interconnects 4S for ground voltage, to prevent occurrence of a withstand voltage-related trouble.

### Embodiment 5

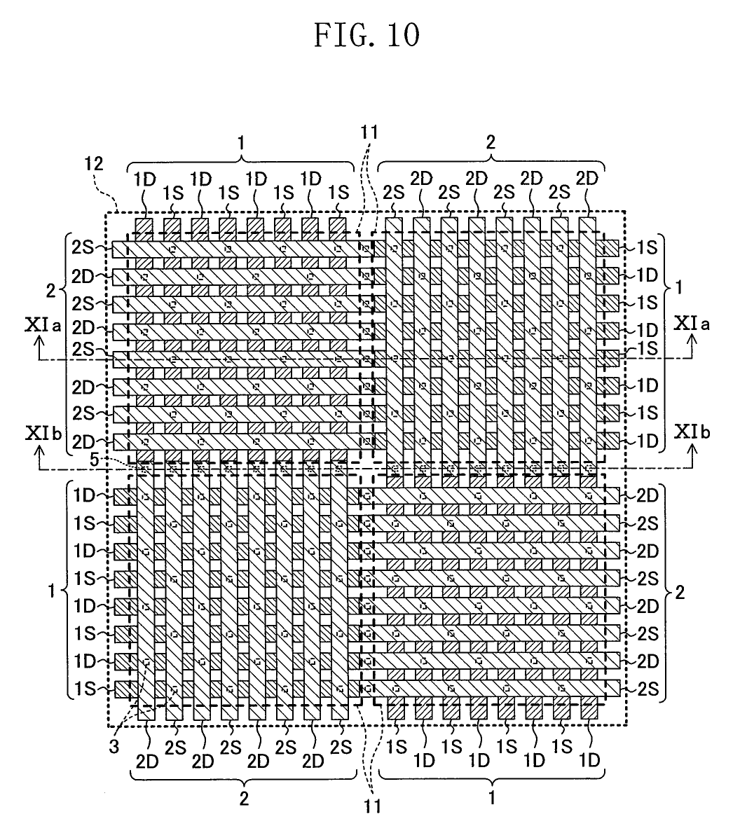

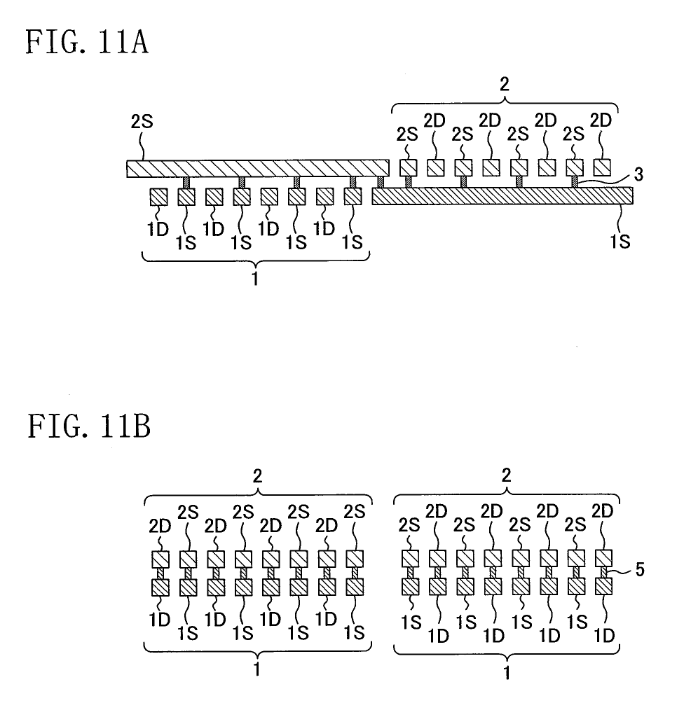

FIG. 10 is a plan view showing a power wiring structure of a semiconductor integrated circuit of Embodiment 5 of the present invention. FIGS. 11A and 11B are cross-sectional views of the power wiring structure of the semiconductor integrated circuit of Embodiment 5, taken along line XIa-XIa and line XIb-XIb in FIG. 10, respectively.

As shown in FIGS. 10, 11A and 11B, the power wiring structure of the semiconductor integrated circuit of Embodiment 5 is composed of a wiring block 12 made of four meshed power arrays 11.

One meshed power array 11 corresponds to a quarter of the power wiring structure shown in FIG. 1. The four meshed power arrays 11 are arranged so that the direction of running of the interconnects 1D and 1S of the wiring layer 1 and the direction of running of the interconnects 2D and 2S of the wiring layer 2 are displaced by 90° every meshed power array 11 (i.e., in any two opposing meshed power arrays 11, the direction of running of the interconnects of the wiring layer 1 in one power array 11 is the same as the direction of running of the interconnects of the wiring layer 2 in the other power array 11, and the direction of running of the interconnects of the wiring layer 2 in the one power array 11 is the same as the direction of running of the interconnects of the wiring layer 1 in the other power array 11), to constitute the wiring block 12.

The interconnects 1D and the interconnects 2D for power supply voltage are electrically connected to each other via contacts 3 formed through a first interlayer insulating film (not shown) at the positions of intersection of these interconnects as viewed from top within one meshed power array 11 and also between any adjacent meshed power arrays 11. Likewise, the interconnects 1S and the interconnects 2S for power supply voltage are electrically connected to each other via contacts 3 formed through the first interlayer insulating film (not shown). The other structure of the power arrays 11 is substantially the same as that of Embodiment 1 described above, and thus the description thereof is omitted here.

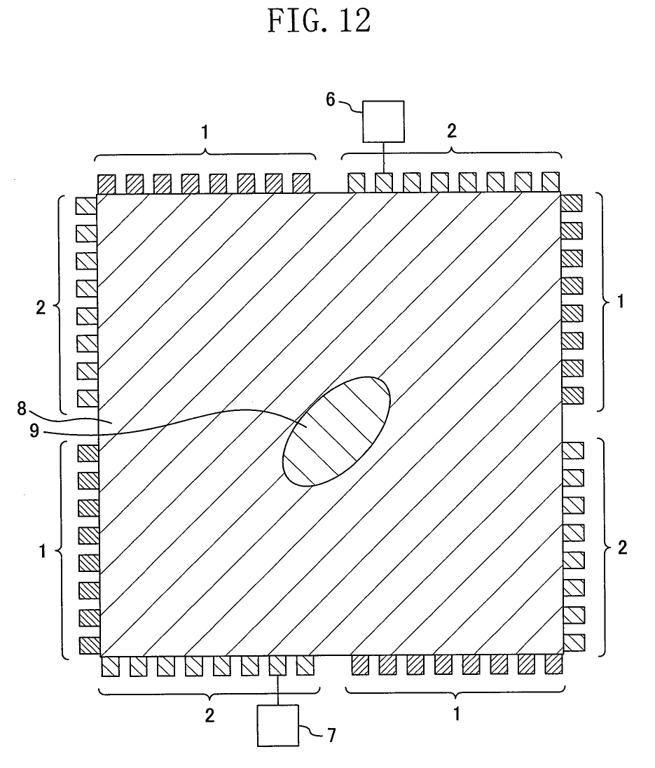

FIG. 12 schematically shows a voltage drop in the semiconductor integrated circuit having the power wiring structure of this embodiment. Specifically, FIG. 12 schematically shows the voltage drop during operation of the semiconductor integrated circuit observed when a power supply voltage is applied via terminals 6 and 7 to the power wiring structure composed of one wiring block 12 made of four power arrays 11 described above. Regions 8 and 9 are as defined in Embodiment 1.

As shown in FIG. 12, in this embodiment, compared with the case of the conventional semiconductor integrated circuit having the power wiring structure (see FIG. 20), the region 10 large in voltage drop no more exists, and the region 8 small in voltage drop has expanded to most of the area with the region 9 middle in voltage drop remaining in a small portion. This therefore indicates that the voltage drop has been widely reduced.

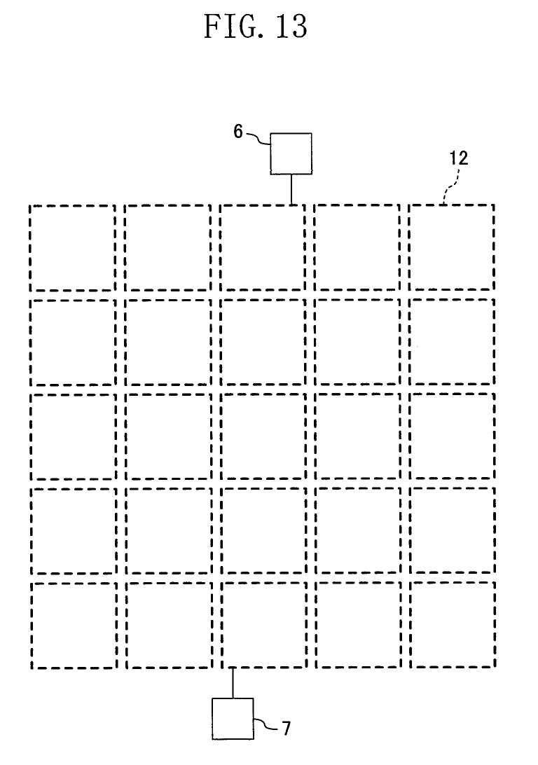

FIG. 13 schematically shows a semiconductor integrated circuit having a power wiring structure composed of a five by five matrix of wiring blocks each of which is the same as the wiring block 12 described above.

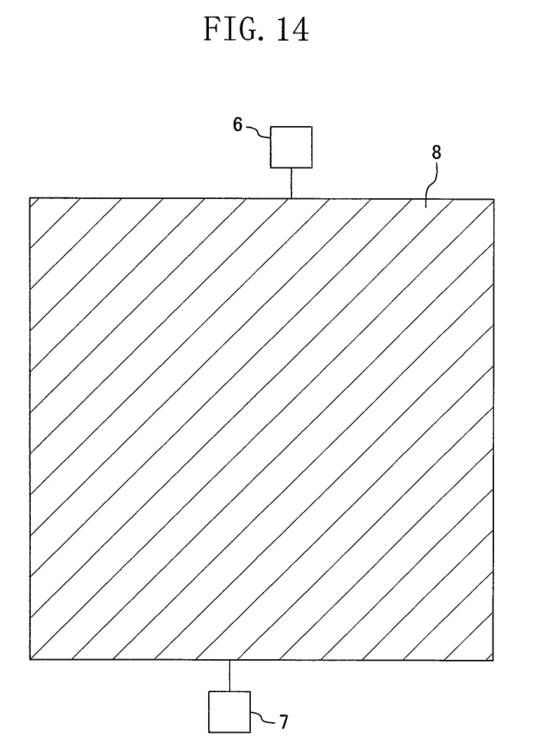

FIG. 14 schematically shows a voltage drop during operation of the semiconductor integrated circuit observed when a power supply voltage is applied via terminals 6 and 7 to the power wiring structure of FIG. 13.

As shown in FIG. 14, in the case of the five by five matrix of wiring blocks 12, compared with the case of the conventional semiconductor integrated circuit having the power wiring structure (see FIG. 20), both the region 10 large in voltage drop and the region 9 middle in voltage drop no more exist, and only the region 8 small in voltage drop exists. This therefore indicates that the voltage drop has been widely reduced.

As described above, the power wiring structure of this embodiment can be configured by appropriately setting the number of wiring blocks 12. As an actual configuration example, assuming that the chip is 3 mm square, for example, a 30 by 30 matrix of meshed power arrays 11 having a size of 100 μm, for example, which constitute wiring blocks 12, may be formed and connected. Although the size of the meshed power array 11 was described as the order of 100 μm, it can be appropriately set depending on the level of the voltage drop. In general, design may be made so that the voltage drop level can be suppressed to 50 mV or less, for example.

As described above, the power wiring structure of this embodiment is composed of the wiring block 12 made of four meshed power arrays 11 arranged so that the direction of running of the interconnects of the wiring layer 1 and the direction of running of the interconnects of the wiring layer 2 are displaced by 90° every meshed power array. Therefore, even when the wiring resistance of the wiring layer 2 is equal to or less than that of the wiring layer 1, having a resistance value 0.5 to 1.0 times as large as that of the wiring layer 1, in which case the voltage drop will conventionally be great in a particular direction, the directivity of the voltage drop in any of the direction of running of the interconnects of the wiring layer 1 and the direction of running of the interconnects of the wiring layer 2 will be suppressed. As a result, the voltage drop of the entire chip can be suppressed.

### Embodiment 6

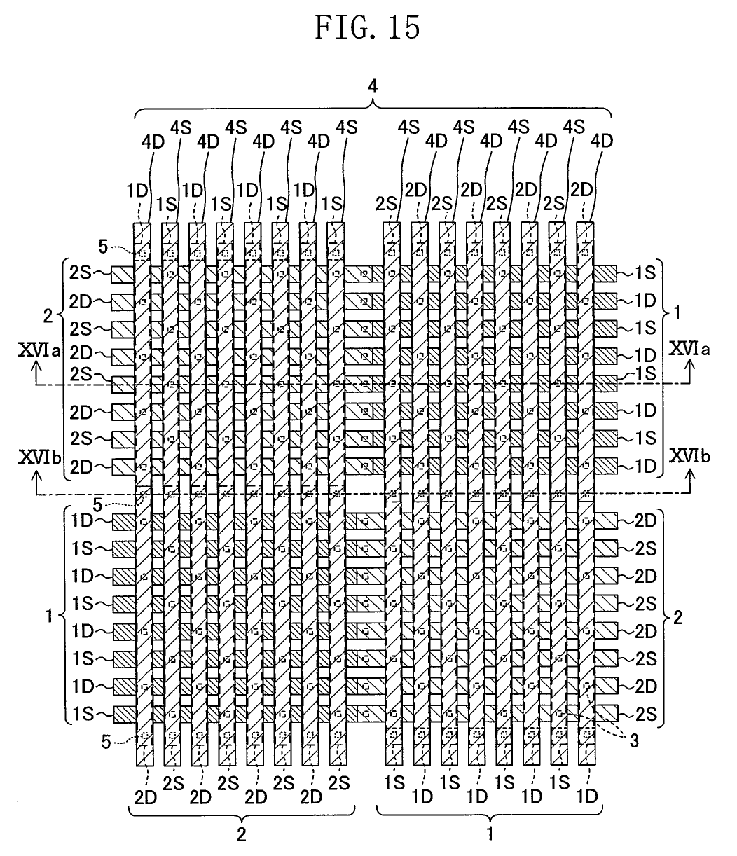

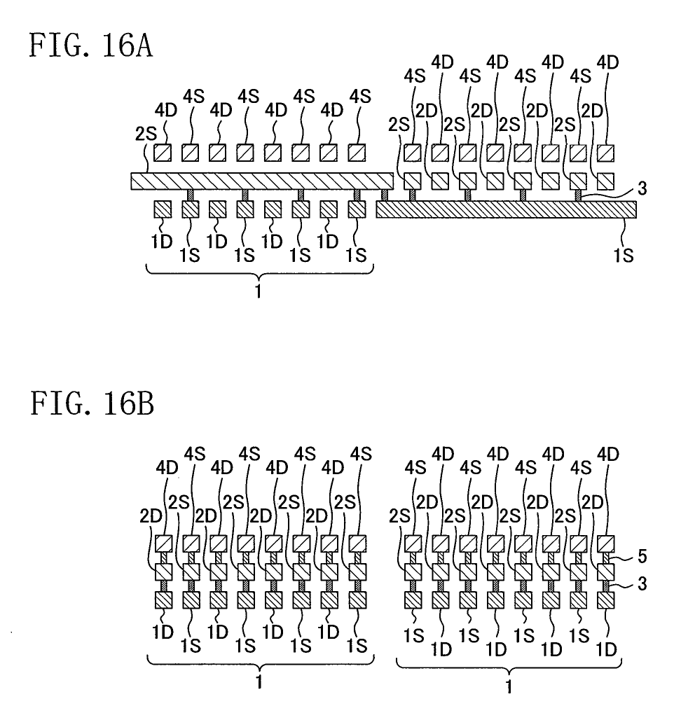

FIG. 15 is a plan view showing a power wiring structure of a semiconductor integrated circuit of Embodiment 6 of the present invention. FIGS. 16A and 16B are cross-sectional views of the power wiring structure of the semiconductor integrated circuit of Embodiment 6, taken along line XVIa-XVIa and line XVIb-XVIb in FIG. 15, respectively.

As shown in FIGS. 15, 16A and 16B, the power wiring structure of the semiconductor integrated circuit of Embodiment 6 is different from the power wiring structure of the semiconductor integrated circuit of Embodiment 5 described above in that a wiring layer 4 is further provided above the wiring layer 2.

More specifically, in the power wiring structure of the semiconductor integrated circuit of Embodiment 6, the wiring layer 4 including a plurality of interconnects 4D and a plurality of interconnects 4S is formed above the wiring layer 2 including the plurality of interconnects 2D and the plurality of interconnects 2S, and the interconnects 4D and 4S run in one direction over the wiring block 12 (see FIG. 10) composed of four meshed power arrays 11 described in Embodiment 5.

The interconnects 2D and the interconnects 4D for power supply voltage are electrically connected to each other via contacts 5 formed through a second interlayer insulating film (not shown) (see FIGS. 15 and 16B) within one meshed power array 11 and also between any adjacent meshed power arrays 11. Likewise, the interconnects 2S and the interconnects 4S for ground voltage are electrically connected to each other via contacts 5 formed through the second interlayer insulating film (not shown) (see FIG. 8). The other structure of the meshed power arrays 11 is substantially the same as that described in Embodiment 5.

As described above, the power wiring structure of this embodiment can obtain substantially the same effect as that in Embodiment 5. In addition, with the interconnects of the wiring layer 4 running in one direction, the meshed power arrays 11 are connected with each other in the same direction, and thus the resistance can be reduced. Hence, the voltage drop can be further reduced.

### Embodiment 7

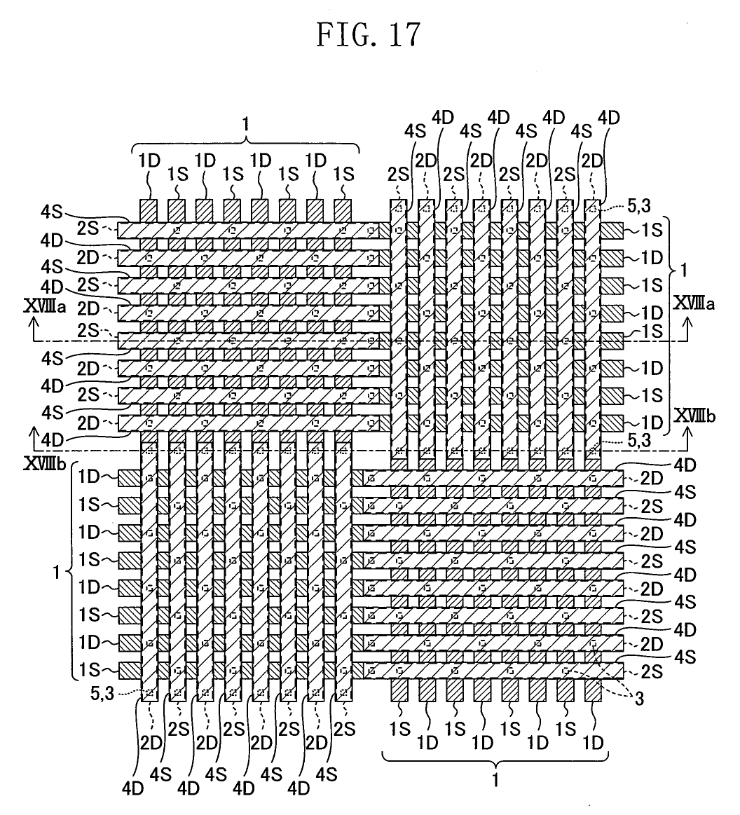

FIG. 17 is a plan view showing a power wiring structure of a semiconductor integrated circuit of Embodiment 7 of the present invention. FIGS. 17A and 17B are cross-sectional views of the power wiring structure of the semiconductor integrated circuit of Embodiment 7, taken along line XVIIIa-XVIIIa and line XVIIIb-XVIIIb in FIG. 17, respectively.

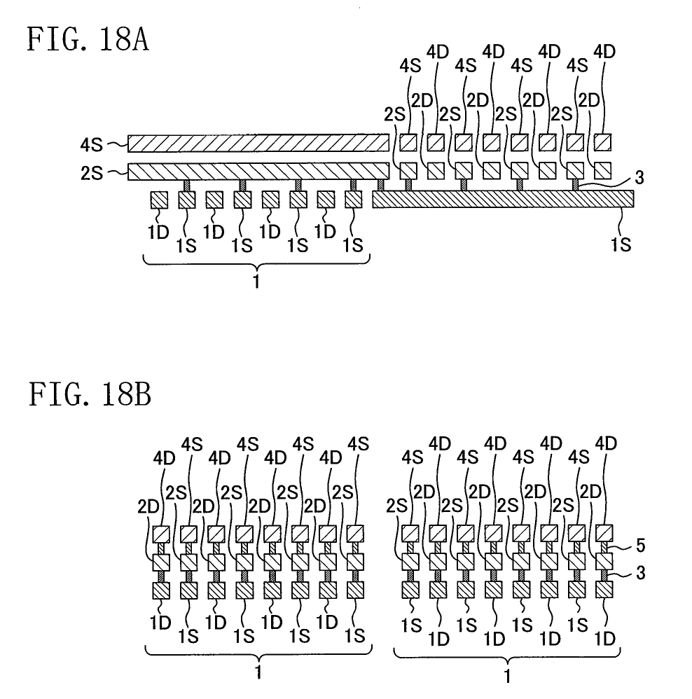

As shown in FIGS. 17, 18A and 18B, the power wiring structure of the semiconductor integrated circuit of Embodiment 7 is different from the power wiring structure of the semiconductor integrated circuit of Embodiment 5 described above in that a wiring layer 4 configured to correspond to each of the underlying meshed power arrays 11 (see FIG. 10) is further provided above the wiring layer 2.

More specifically, in the power wiring structure of the semiconductor integrated circuit of Embodiment 7, the wiring layer 4 including a plurality of interconnects 4D and a plurality of interconnects 4S is formed above the wiring layer 2 including the plurality of interconnects 2D and the plurality of interconnects 2S to correspond to each of the meshed power arrays 11 (see FIG. 10) The interconnects 4D and 4S run in the same direction as the direction of running of their corresponding interconnects 2D and 2S. In other words, the direction of running of the interconnects 4D and 4S in one of any two adjacent meshed power arrays 11 is displaced by 90° with respect to the direction of running of the interconnects 4D and 4S in the other meshed power array 11.

The interconnects 2D and the interconnects 4D for power supply voltage are electrically connected to each other via contacts 5 formed through a second interlayer insulating film (not shown) within one meshed power array 11 and also between any adjacent meshed power arrays 11 (see FIGS. 17 and 18B). Likewise, the interconnects 2S and the interconnects 4S for ground voltage are electrically connected to each other via contacts 5 formed through the second interlayer insulating film (not shown) (see FIG. 8). The other structure of the meshed power arrays 11 is substantially the same as that described in Embodiment 5.

As described above, the power wiring structure of this embodiment can obtain substantially the same effect as that in Embodiment 5. In addition, the interconnects of the wiring layer 4 run in the same direction as the interconnects of the wiring layer 2 for each meshed power array 11, and the wiring layer 4 is electrically connected with the wiring layer 2 via the contacts 5 to give the same potential. The resistance can therefore be reduced, and thus the voltage drop can be further reduced. Moreover, with the wiring layers 2 and 4 being at the same potential, it is unnecessary to consider the insulation property of the second interlayer insulating film existing between the wiring layer 4 and the wiring layer 2. This embodiment therefore provides an advantageous structure for reliability of the semiconductor integrated circuit.

In the above embodiments, description was made centering on the features of the power wiring structure, and thus description of other known components such as interlayer insulating films, normally formed between the wiring layers and between interconnects, other wiring layers formed under the wiring layer 1 and transistors is omitted here.

The present invention, which can suppress the drop of the power supply voltage in a chip, is useful for stable operation of a semiconductor integrated circuit. Also, since the voltage drop can be suppressed efficiently, the present invention is also useful for reduction in chip area.

While the present invention has been described in preferred embodiments, it will be apparent to those skilled in the art that the disclosed invention may be modified in numerous ways and may assume many embodiments other than those specifically set out and described above. Accordingly, it is intended by the appended claims to cover all modifications of the invention which fall within the true spirit and scope of the invention.

What is claimed is:

1. A semiconductor integrated circuit comprising:
a first wiring layer including a plurality of first interconnects formed to run in a first direction;
a second wiring layer formed above the first wiring layer, the second wiring layer including a plurality of second interconnects formed to run in a second direction vertical to the first direction; and
a third wiring layer formed above the second wiring layer, the third wiring layer including a plurality of third interconnects formed to run in the same direction as the second direction.

2. The semiconductor integrated circuit of claim 1, wherein the second wiring layer and the third wiring layer are electrically connected to each other.

3. The semiconductor integrated circuit of claim 1, wherein the first wiring layer and the second wiring layer are made of copper, and
the third wiring layer is made of aluminum.

4. The semiconductor integrated circuit of claim 1, wherein the third wiring layer is made of the same material as pads.

5. The semiconductor integrated circuit of claim 1, wherein each of the plurality of third interconnects is wider than each of the plurality of second interconnects.

6. The semiconductor integrated circuit of claim 1, wherein each of the plurality of third interconnects is formed to cover two adjacent ones of the plurality of second interconnects.

7. The semiconductor integrated circuit of claim 6, wherein each of the plurality of third interconnects is not formed above an interconnect located next to the two adjacent ones among the plurality of second interconnects.

8. The semiconductor integrated circuit of claim 7, wherein the first wiring layer includes interconnects for power supply voltage as the first interconnects and interconnects for ground voltage as the first interconnects arranged to alternate one by one,
the second wiring layer includes interconnects for power supply voltage as the second interconnects and interconnects for ground voltage as the second interconnects arranged to alternate every three interconnects, and
the third wiring layer includes interconnects for power supply voltage as the third interconnects and interconnects for ground voltage as the third interconnects arranged to alternate one by one.

9. The semiconductor integrated circuit of claim 1, wherein each of the plurality of third interconnects has a portion formed to cover two adjacent ones of the plurality of second interconnects and a portion formed to cover only one of the two adjacent ones, along the running of the third interconnect.

10. The semiconductor integrated circuit of claim 9, wherein the first wiring layer includes interconnects for power supply voltage as the first interconnects and interconnects for ground voltage as the first interconnects arranged to alternate one by one,
the second wiring layer includes interconnects for power supply voltage as the second interconnects and interconnects for ground voltage as the second interconnects arranged to alternate every two interconnects, and
the third wiring layer includes interconnects for power supply voltage as the third interconnects and interconnects for ground voltage as the third interconnects arranged to alternate one by one.

11. A semiconductor integrated circuit comprising:
at least one wiring block including a two by two matrix of meshed power arrays, each of the meshed power arrays having a first wiring layer including a plurality of first interconnects and a second wiring layer formed above the first wiring layer, the second wiring layer including a plurality of second interconnects formed to run in a direction vertical to the direction of running of the plurality of first interconnects, the meshed power arrays being lined in the direction of running of the plurality of first interconnects and in the direction of running of the plurality of second interconnects,
the direction of running of the plurality of first interconnects in one of the meshed power arrays constituting the wiring block is displaced by 90° with respect to the direction of running of the plurality of first interconnects in a meshed power array adjacent to the one meshed power array, and
the direction of running of the plurality of second interconnects in one of the meshed power arrays constituting the wiring block is displaced by 90° with respect to the direction of running of the plurality of second interconnects in a meshed power array adjacent to the one meshed power array.

12. The semiconductor integrated circuit of claim 11, further comprising a third wiring layer including a plurality of third interconnects formed above the second wiring layer,
wherein the plurality of third interconnects run in one direction above all the meshed power arrays, and the direction is the same as the direction of running of the plurality of first interconnects or the direction of running of the plurality of second interconnects in each of the meshed power arrays.

13. The semiconductor integrated circuit of claim 11, further comprising a third wiring layer including a plurality of third interconnects formed above the second wiring layer in each of the meshed power arrays,
wherein the plurality of third interconnects run in the same direction as the direction of running of the plurality of second interconnects in each of the meshed power arrays.

14. The semiconductor integrated circuit of claim 11, wherein the second wiring layer and the third wiring layer are electrically connected to each other.
